(19) United States
(12) Patent Application Publication
(10) Pub. No.: US 2019/0061336 A1
(43) Pub. Date: Feb. 28, 2019

(54) THREE-DIMENSIONAL PRINTING METHOD AND THREE-DIMENSIONAL PRINTING APPARATUS USING THE SAME

(71) Applicants: XYZprinting, Inc., New Taipei City (TW); Kinpo Electronics, Inc., New Taipei City (TW)

(72) Inventors: Kuo-Yen Yuan, New Taipei City (TW); Yi-Ying Lin, New Taipei City (TW)

(73) Assignees: XYZprinting, Inc., New Taipei City (TW); Kinpo Electronics, Inc., New Taipei City (TW)

(21) Appl. No.: 15/690,207

(22) Filed: Aug. 29, 2017

(51) Int. Cl. B33Y 50/02; B29C 64/393; B29C 64/386

(52) U.S. Cl. CPC B33Y 50/02; H05K 3/102; B29C 64/386; B29C 64/393

(57) ABSTRACT

A three-dimensional (3D) printing method for forming a 3D object layer by layer is provided. The 3D printing method is applicable to a 3D printing apparatus having an input device, and includes: sequentially printing a plurality of layers of the 3D object; obtaining an adjustment signal through the input device when printing a layer of the plurality of layers, where the adjustment signal is used for adjusting a printing parameter; and adjusting the printing parameter for printing another layer of the plurality of layers in response to the obtained adjustment signal. In addition, a 3D printing apparatus using the 3D printing method is also provided.

### BACKGROUND

### Field of the Invention

The invention is directed to a three-dimensional (3D) printer, and more particularly, to a 3D printing method that adjusts the printing parameter and a 3D printing apparatus using the 3D printing method.

### Description of Related Art

Along with the development of technologies, a three-dimensional (3D) printing technique has become one of the most important techniques under development. The 3D printing technique is also referred to as an additive manufacturing (AM) technique which is a type of rapid prototyping (RP) technique and can establish a 3D object through a layer-by-layer printing manner based on a digital forming drawing file by using bonding materials, such as powdered metals or plastic materials.

The print head of the current 3D printing apparatus is mainly comprised of a feeding tube, a heating device and a nozzle. Most of raw materials used are hot-melt forming materials. These forming materials are solid at room temperature. The solid forming material is transmitted to the nozzle through the feeding tube, hot-melted by the heating device and extruded from the nozzle, so as to form a 3D object layer by layer. Different materials have different characteristics, therefore the printing temperature for melting the forming material is usually default according to the type of the used material.

However, the default temperature cannot be suitable for printing every 3D object. For example, it is found that portions of a 3D object having large cross-sectional areas crack sometimes when using the material of Acrylonitrile Butadiene Styrene (ABS). Such deficiencies probably result from an improper printing temperature or printing speed when printing these portions. Accordingly, it would be helpful to provide a mechanism for curing such deficiencies.

### SUMMARY

The invention provides a 3D printing method and a 3D printing apparatus using the 3D printing method, which provide an opportunity for real-time controlling the printing parameters such as the printing temperature during a printing procedure.

An exemplary embodiment of the invention provides a 3D printing method for forming a 3D object layer by layer. The 3D printing method is applicable to a 3D printing apparatus having an input device, and includes: sequentially printing a plurality of layers of the 3D object; obtaining an adjustment signal through the input device when printing a layer of the plurality of layers, where the adjustment signal is used for adjusting a printing parameter; and adjusting the printing parameter for printing another layer of the plurality of layers in response to the obtained adjustment signal.

Another exemplary embodiment of the invention provides a 3D printing apparatus includes a print head, an input device and a controller. The print head is configured to form a 3D object layer by layer. The controller is coupled to the print head and the input device, and configured to sequentially printing a plurality of layers of the 3D object by the print head. The controller obtains an adjustment signal through the input device when printing a layer of the plurality of layers, and adjusting a printing parameter for printing another layer of the plurality of layers in response to the obtained adjustment signal, wherein the adjustment signal is used for adjusting the printing parameter.

Based on the above, the 3D printing method and the 3D printing apparatus provided in the embodiments of the invention is capable of adjusting the printing parameters during the printing procedure. Accordingly, convenience and flexibility of 3D printing can be improved. In addition, a user can real-time adjust the printing parameters as desired when his/her 3D object is being printing, thus the printing quality can be well-controlled.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a schematic block diagram of a three-dimensional printing apparatus according to an embodiment of the invention.

FIG. 2 illustrates a flowchart of a three-dimensional printing method according to an embodiment of the invention.

FIG. 3 illustrates a flowchart of obtaining the adjustment signal according to an embodiment of the invention.

FIG. 4 illustrates a schematic diagram of a prompt message displayed on a display according to an embodiment of the invention.

### DESCRIPTION OF EMBODIMENTS

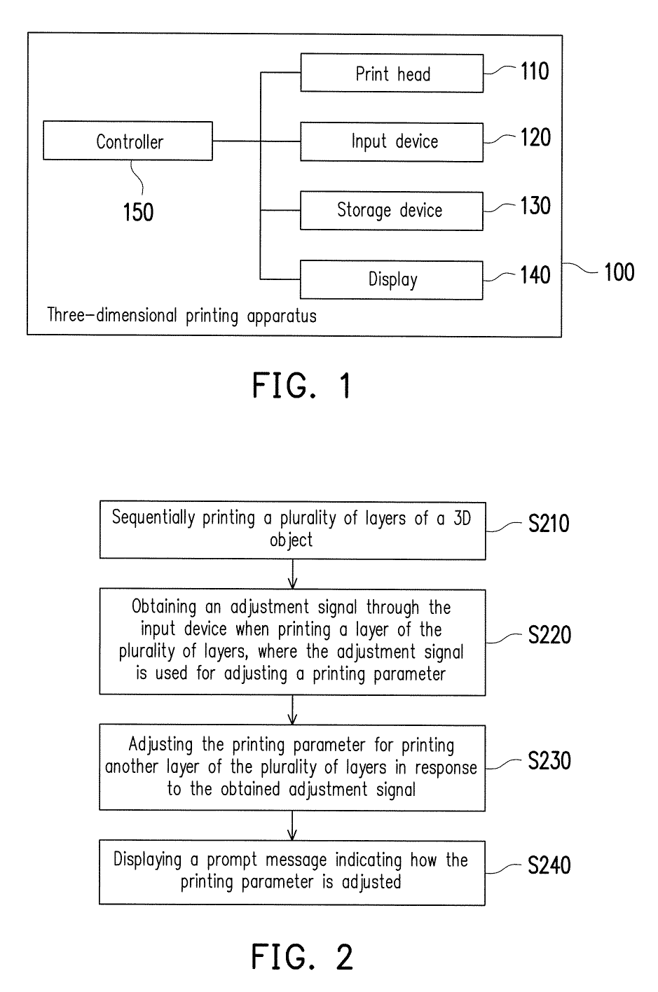

FIG. 1 illustrates a schematic block diagram illustrating a three-dimensional (3D) printing apparatus according to an embodiment of the invention. Referring to FIG. 1, a 3D printing apparatus 100 includes a print head 110, an input device 120, a storage device 130, a display 140, and a controller 150. The 3D printing apparatus 100 is, for example, a 3D printer that forms the 3D object layer by layer.

The print head 110 is, for example, a melting head, which heats a filament formed by a laminated material to a printing temperature, and sprays the laminated material in a melting state to form a 3D object layer by layer.

The input device 120 may receive at least one type of input signal. For example, the input device 120 may be one or a combination of: at least one physical button disposed on the 3D printing apparatus, a wireless transceiver, and an audio input such as a microphone, but which are not limited herein. In one embodiment of the invention, the input device 120 includes at least the audio input for receive voice signals so that the 3D printing apparatus 100 provides a function of voice control.

The storage device 130 may be any type of fixed or portable random access memory (RAM), read-only memory (ROM), flash memory, or similar components, or a combination of the above components, which is not limited herein. In one embodiment of the invention, the storage device 130 is configured to store a sequence of printing commands to be executed for printing the 3D object. In another embodiment of the invention that the 3D printing apparatus 100 provides the function of voice control, the storage device 130 further stores a database supporting the function of voice control. Details of the printing commands, the function of voice control and the database supporting the same will be illustrated in the following descriptions.

The display 140 provides information of the printing status. The display 140 may be, for example, a liquid-crystal display (LCD) disposed on the 3D printing apparatus 100. In some cases, the LCD is combined with the input device 120, such that the input device 120 and the display 140 can be implemented together as a touch screen.

The controller 150 is coupled to the print head 110, the input device 120, the storage device 130 and the display 140, and is in charge of the overall operations of the 3D printing apparatus 100. The controller 150 may be a programmable device for general purpose or special purpose, for example, a central processing unit (CPU), a micro-processor or an embedded controller.

In one embodiment of the invention, the controller 150 may transfer an original image file (e.g., .STL, .SCAD, .OBJ, 0.3DS, .AMF, etc.) depicting a 3D object to a G-code file including multiple rows of G-code, where each row of the G-code stands for a printing command of the print head 110. After that, the controller 150 may sequentially execute the printing commands (the rows of the G-code) to control the print head 110 for printing the 3D object. Exemplary example of some rows of the G-code are listed in Table. 1 below.

TABLE 1

| Row No. | G-code | | | | |
|---|---|---|---|---|---|
| 60 | G1 | Z25.250 | F2700.000 | M104 | S210 |
| 61 | G1 | X82.000 | Y72.000 | F300.000 | E8 |
| 62 | G1 | X67.000 | Y77.000 | E10.68 | |
| 63 | G1 | X67.000 | Y72.000 | E11.15 | |
| 64 | G1 | Z25.550 | F2700.000 | | |
| 65 | G1 | X82.000 | Y72.000 | F300.000 | E8 |
| 66 | G1 | X67.000 | Y77.000 | E10.68 | |
| 67 | G1 | X67.000 | Y72.000 | E11.15 | |

As shown in Table. 1, the 3D printing apparatus 100 may sequentially execute multiple rows of the G-code named G1 in this embodiment. Each row of the G-code mainly includes a destination position of the print head 110.

Referring to the G-code of row No. 61, the field “F300.000” has the controller 150 control the print head 110 to move in a speed rate of 300 mm/min, namely, “F300.000” represents a printing parameter of “moving speed of the print head 110” with value of 300 mm/min. In some cases, a row of the G-code does not have the printing parameter of “moving speed” (e.g., “FXXX”) of the print head 110, which indicates that the controller 150 does not change the moving speed of the print head 110 when executing the row of the G-code. As per the field “X82.000 Y72.000”, it represents a destination coordinate (i.e., (82, 72)) where the print head 110 is finally located after the execution of the G-code of row No. 61 is completed, namely, “X82.000 Y72.000” represents a printing parameter of “location of the print head 110” with value of (82, 72). As per the field “E8”, it has the controller 150 control the filament or material extruded from the print head 110 is 8 mm, namely, “E8” represents a printing parameter of “feeding amount of the print head 110” with value of 8 mm.

For instance, when the controller 150 executes the G-code of row No. 61, the print head 110 moves in the speed of 300 mm/min toward the destination coordinate (82, 72) and the material extruded from the print head 110 is 8 mm during the process of moving. In the same way, when the controller 150 executes the G-code of row No. 62, the print head 110 continues to move in the speed of 300 mm/min toward a destination coordinate (67, 77), and the material extruded from the print head 110 is 10.68 mm during the process of moving. In other words, 2.68 mm of the material is fed when the G-code of row No. 62 is executed by the controller 150.

Referring to the G-code of rows No. 60 and 64, the field “Z25.250” has the controller 150 lift the print head 110 to a specific height, and the field “Z25.500” has the controller 150 lift the print head 110 to another specific height. That is to say, the controller 150 prints one layer (e.g., the n^{th} layer) of the 3D object by executing the G-code of rows No. 60 to 63, and lifts the print head 110 to start printing a next layer (e.g., the (n+1)^{th} layer) of the 3D object when executing the G-code of row No. 64. Namely, “Z25.250” and “Z25.500” represents the printing parameter of “printing height” with values of 25.250 and 25.500. As per the field “M104 S210”, it has the controller 150 control the print head 110 to heat the laminated material to a printing temperature of 210 Celsius degrees, namely, “M104 S210” represents a printing parameter of “printing temperature” with value of 210° C.

In the embodiment, the printing parameter can be a “moving speed of the print head 110”, a “location of the print head 110”, a “feeding amount from the print head 110”, a “printing height”, or a “printing temperature”, but which is not limited in the invention. In other embodiments, the printing parameter can be any other parameter that affects the printing procedure.

FIG. 2 illustrates a flowchart of a 3D printing method according to an embodiment of the invention. The 3D printing method may be performed by the 3D printing apparatus 100 of the embodiment of FIG. 1. Therefore, the 3D printing method may be illustrated by referring to the aforementioned 3D printing apparatus 100 in the present embodiment.

Referring to FIG. 1 and FIG. 2, in order to print a 3D object, the controller may sequentially print a plurality of layers of the 3D object (S210). To be specific, a 3D object may be formed by multiple layers. In one embodiment, the controller 150 may load a G-code file including multiple rows of the G-code (i.e., the printing commands), each printing command is corresponding to one single row of the G-code as described above. After that, the controller 150 starts the printing procedure and executes the printing commands sequentially. As mentioned before, the controller 150 may lift the print head 110 to start printing a next layer whenever a printing command adjusting the printing height is executed, such that the 3D object can be printed layer by layer. The G-code file may be, for example, originally stored in the storage device 130 or received from the input device 120, which is not limited in the invention.

During the printing procedure, the controller 150 obtains an adjustment signal through the input device 120 when printing a specific layer of the 3D object (S220). To be specific, the adjustment signal is used for adjusting a printing parameter of the printing procedure. As such, the adjustment signal includes information of a printing parameter specifically indicating what is being adjusted, and an adjustment behavior of the printing parameter specifically indicating how the printing parameter is adjusted. For example, an adjustment signal may be used for rising the printing temperature that the print head 110 heats the laminated material. In this case, the adjustment signal should be corresponding to the printing parameter of “printing temperature”, meanwhile corresponding to the adjustment behavior of “increase”.

In one embodiment, user may generate the adjustment signal by at least one physical or virtual button disposed on the 3D printing apparatus 100, therefore the adjustment signal may be received through the at least one physical or virtual button. In one embodiment, user may generate a wireless signal by using a remote controller, and the wireless signal may be received through a wireless transceiver of the 3D printing apparatus 100 and transferred to the adjustment signal by the controller 150.

Advantageously, user may generate the adjustment signal through the voice in one embodiment of the invention, a voice signal generated by the user may be received through an audio input (e.g., a microphone) of the 3D printing apparatus 100 and be transferred to the adjustment signal by the controller 150 using technologies such as semantic analysis. In one embodiment, for supporting the function of voice control, the storage device 130 stores a database that records, for example, multiple nouns and the printing parameter corresponding to each noun. As per each of the nouns, the database records multiple verbs and the adjustment behavior corresponding to each verb.

For example, for the noun “temperature” corresponding to the printing parameter “printing temperature”, the verbs “rise” and “increase” may both correspond to the adjustment behavior “increase”, and the verbs “drop” and “decrease” may both correspond to the adjustment behavior “decrease”. In such case, when “temperature” and “rise” are extracted from a voice signal, which means that the value of the printing parameter “printing temperature” will be increased accordingly.

For another example, for the noun “speed” corresponding to the printing parameter “moving speed of the print head 110”, the verbs “rise” and “increase” may both correspond to the adjustment behavior “increase”, and the verbs “drop” and “decrease” may both correspond to the adjustment behavior “decrease”. In such case, when “speed” and “rise” are extracted from a voice signal, which means that the value of the printing parameter “moving speed of the print head 110” will be increased accordingly.

For still another example, for the noun “retract length” corresponding to the printing parameter “feeding amount from the print head 110”, the verb “rise” and “increase” may both correspond to the adjustment behavior “decrease”, and the verbs “drop” and “decrease” may both correspond to the adjustment behavior “increase”. In such case, when “retract length” and “increase” are extracted from a voice signal, which means that the value of the printing parameter “feeding amount from the print head 110” will be decreased accordingly.

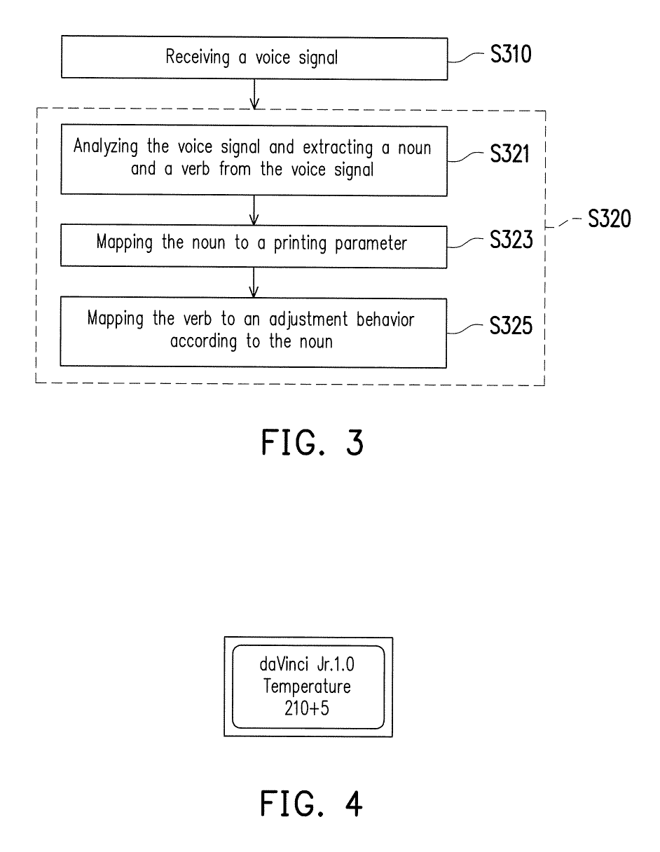

FIG. 3 illustrates a flowchart of obtaining the adjustment signal according to an embodiment of the invention. Referring to FIG. 3, the controller 150 receives a voice signal through the input device 120 (S310), then transfers the voice signal to an adjustment signal (S320).

To be specific, after receiving the voice signal, the controller 150 may analyze the voice signal and to extract a noun and a verb from the voice signal (S321). For example, the received voice signal says “temperature rises”. The controller 150 may perform a semantic analysis on the voice signal to extract the noun “temperature” and the verb “rise” from the voice signal. For another example, the received voice signal says “rise the speed, please”. The controller 150 may perform a semantic analysis on the voice signal to extract the noun “speed” and the verb “rise” from the voice signal. For still another example, the received voice signal says “increase the retract length”. The controller 150 may perform a semantic analysis on the voice signal to extract the noun “retract length” and the verb “increase” from the voice signal.

Subsequently, the controller 150 may map the noun to a printing parameter (S323), and map the verb to an adjustment behavior according to the noun (S325). For example, regarding the extracted “temperature” and “rise”, the controller 150 may consult a database stored in the storage device 130, map the “temperature” to the printing parameter “printing temperature”, and map the “rise” to the adjustment behavior “increase”. As a result, an adjustment signal used for rising the printing temperature is thus transferred from the voice signal. For another example, regarding the extracted “speed” and “rise”, the controller 150 may consult a database stored in the storage device 130, map the “speed” to the printing parameter “moving speed of the print head 110”, and map the “rise” to the adjustment behavior “increase”. As a result, an adjustment signal used for increasing the moving speed of the printing head 110 is thus transferred from the voice signal. For still another example, regarding the extracted “retract length” and “increase”, the controller 150 may consult a database stored in the storage device 130, map the “retract length” to the printing parameter “feeding amount from the print head 110”, and map the “increase” to the adjustment behavior “decrease”. As a result, an adjustment signal used for increase the retract length is thus transferred from the voice signal.

It is noted that the embodiment of FIG. 3 is mere an exemplary embodiment, and how the voice signal is transferred to the adjustment signal is not limited in the invention. In another embodiment, the database may further record comparative adjectives such as “faster” or “slower”, and each comparative adjective may correspond to an adjustment behavior. In still another embodiment, the database may further record nouns composed of a number and a unit, such as “5 mm/sec” or “10° C.”, and each noun may correspond to an adjustment behavior as well. One skilled in the art can obtain enough knowledge of how to transfer a voice signal to an adjustment signal for adjusting the printing parameter by the controller 150, which is not repeatedly described in the description.

Referring back to FIG. 2, in response to the obtained adjustment signal, the controller 150 may adjust a specific printing parameter for printing another layer of the plurality of layers (S230), where information of the specific printing parameter is in the obtained adjustment signal as mentioned before. For providing the printing status, the controller 150 may display a prompt message on the display 140 when the printing parameter is adjusted (S240), where the prompt message indicates how the printing parameter is adjusted.

In one embodiment, the adjustment signal may be used for adjusting a printing temperature and obtained when the controller 150 is printing the n layer of the plurality of layers of the 3D object, where n is a natural number. In response to the obtained adjustment signal that adjusts the printing temperature, the controller 150 may adjust the printing parameter “printing temperature” for printing the (n+1)^{th} layer of the plurality of layers of the 3D object according to the adjustment signal, and display a prompt message since any printing parameter is adjusted.

For descriptive convenience, the G-code listed in Table. 1 is taken as an example:

TABLE 1

| Row No. | G-code | | | | |
|---|---|---|---|---|---|
| 60 | G1 | Z25.250 | F2700.000 | M104 | S210 |
| 61 | G1 | X82.000 | Y72.000 | F300.000 | E8 |
| 62 | G1 | X67.000 | Y77.000 | E10.68 | |
| 63 | G1 | X67.000 | Y72.000 | E11.15 | |
| 64 | G1 | Z25.550 | F2700.000 | | |
| 65 | G1 | X82.000 | Y72.000 | F300.000 | E8 |
| 66 | G1 | X67.000 | Y77.000 | E10.68 | |
| 67 | G1 | X67.000 | Y72.000 | E11.15 | |

In this embodiment, an adjustment signal for increasing the printing temperature is obtained when the controller 150 is executing the G-code of row No. 62 (i.e., the 62^{th} command) for printing the n^{th} layer of the 3D object. In response thereto, the controller 150 may find the G-code of row No. 64 (i.e., the 64^{th} command) having the printing parameter of “printing height” (i.e., Z25.500) that lifts the print head 110 and starts to print the (n+1)^{th} layer of the object, then insert the printing parameter “printing temperature” into the found printing command (i.e., the 64^{th} command). For example, the printing parameter of “printing temperature” is set to increase/decrease±5° C. in response to one adjustment signal with adjustment behavior of “increase/decrease” in the embodiment. Accordingly, the G-code will be adjusted as listed in Table. 2 shown below. In this embodiment, a preset range (e.g., 170° C. to 240° C.) of the printing temperature is default in the controller 150. Therefore, the printing parameter of “printing temperature” is confined within the range of “M104 S170” to “M104 S240”, such that the temperature that the print head 110 heats the laminated material is confined within 170° C. to 240° C.

TABLE 2

| Row No. | G-code | | | | |
|---|---|---|---|---|---|
| 60 | G1 | Z25.250 | F2700.000 | M104 | S210 |
| 61 | G1 | X82.000 | Y72.000 | F300.000 | E8 |
| 62 | G1 | X67.000 | Y77.000 | E10.68 | |
| 63 | G1 | X67.000 | Y72.000 | E11.15 | |
| 64 | G1 | Z25.550 | F2700.000 | M104 | S215 |
| 65 | G1 | X82.000 | Y72.000 | F300.000 | E8 |
| 66 | G1 | X67.000 | Y77.000 | E10.68 | |
| 67 | G1 | X67.000 | Y72.000 | E11.15 | |

As shown in Table. 2, the “M104 S215” is inserted into the G-code of row No. 64 in response to the adjustment signal, since the G-code of row No. 64 is for printing a next layer of the 3D object. As a result, the print head 110 would heat the laminated material to 215° C. when the controller 150 executes the G-code of row No. 64, and the prompt message would be displayed on the display 140 as shown in FIG. 4.

In summary, by adopting the 3D printing method and 3D printing apparatus provided in the embodiments of the invention, the printing parameters, such as printing temperature, can be adjusted during the printing procedure. Accordingly, convenience and flexibility of 3D printing can be improved. For instance, a portion of an object to be printed has a larger cross-sectional area, while another portion of the object has a smaller cross-sectional area. Therefore, the print head can heat the laminated material to a higher temperature when printing the portion having the larger cross-sectional area, and heat the laminated material to a lower temperature when printing the portion having the smaller cross-sectional area. Thus, the printing quality can be well-controlled. Additionally, the function of voice control is provided in one embodiment of the invention. By using the function of voice control, the users may conveniently and real-time adjust the printing parameters during the printing procedure as desired.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A three-dimensional (3D) printing method for forming a 3D object layer by layer, applicable to a 3D printing apparatus comprising an input device, comprising:
sequentially printing a plurality of layers of the 3D object;
obtaining an adjustment signal through the input device when printing a layer of the plurality of layers, wherein the adjustment signal is used for adjusting a printing parameter; and
adjusting the printing parameter for printing another layer of the plurality of layers in response to the obtained adjustment signal.

2. The 3D printing method as claimed in claim 1, wherein the obtained adjustment signal is used for adjusting a printing temperature.

3. The 3D printing method as claimed in claim 2, wherein obtaining the adjustment signal through the input device when printing the layer of the plurality of layers comprises:
obtaining the adjustment signal through the input device when printing the n^{th} layer of the plurality of layers, wherein adjusting the printing temperature for printing the another layer of the plurality of layers in response to the obtained adjustment signal comprises:
adjusting the printing temperature for printing the (n+1)^{th} layer of the plurality of layers according to the adjustment signal, wherein n is a natural number.

4. The 3D printing method as claimed in claim 3, further comprising:
displaying a prompt message on a display when the printing temperature is adjusted.

5. The 3D printing method as claimed in claim 1, wherein obtaining the adjustment signal through the input device comprises:
receiving a voice signal; and
transferring the voice signal to the adjustment signal.

6. The 3D printing method as claimed in claim 5, wherein transferring the voice signal to the adjustment signal comprises:
analyzing the voice signal and extracting a noun and a verb from the voice signal;
mapping the noun to the printing parameter;
mapping the verb to an adjustment behavior according to the noun.

7. The 3D printing method as claimed in claim 6, wherein adjusting the printing parameter when printing the another layer of the plurality of layers in response to the obtained adjustment signal comprises:
adjusting the mapped printing parameter for printing the another layer of the plurality of layers according to the mapped adjustment behavior.

8. The 3D printing method as claim in claim 2, wherein the printing temperature is confined within a preset range.

9. The 3D printing method as claimed in claim 1, wherein the printing parameter comprises one or a combination of a moving speed of a print head, a location of the print head, a feeding amount from the print head, a printing height, and a printing temperature.

10. The 3D printing method as claimed in claim 1, wherein each of the printing commands corresponds to a single row of G-code.

11. A three-dimensional (3D) printing apparatus, comprising:
a print head, configured to form a 3D object layer by layer;
an input device; and
a controller, coupled to the print head and the input device, and configured to sequentially printing a plurality of layers of the 3D object by the print head,
wherein the controller obtains an adjustment signal through the input device when printing a layer of the plurality of layers, and adjusting a printing parameter for printing another layer of the plurality of layers in response to the obtained adjustment signal, wherein the adjustment signal is used for adjusting the printing parameter.

12. The 3D printing apparatus as claimed in claim 11, wherein the adjustment signal obtained through the input device is used for adjusting a printing temperature.

13. The 3D printing apparatus as claimed in claim 12, wherein the controller receives the adjustment signal when printing the n^{th} layer of the plurality of layers, and adjusts the printing temperature for printing the (n+1)^{th} layer of the plurality of layers according to the adjustment signal, wherein n is a natural number.

14. The 3D printing apparatus as claimed in claim 13, further comprising:
a display coupled to the controller, configured to display a prompt message when the printing temperature is adjusted.

15. The 3D printing apparatus as claimed in claim 11, wherein the input device receives a voice signal, and the controller transfers the voice signal to the adjustment signal.

16. The 3D printing apparatus as claimed in claim 15, further comprising:
a storage device coupled to the controller, configured to store a database, wherein the database comprises a plurality of nouns, each noun corresponds to a printing parameter and a plurality of verbs, and each verb corresponds to an adjustment behavior,
wherein the controller analysis the voice signal and extracts a noun and a verb from the voice signal, wherein the controller further consults the database to map the extracted noun to the printing parameter, and to map the extracted verb to the adjustment behavior according to the noun.

17. The 3D printing apparatus as claimed in claim 16, wherein the controller adjusts the mapped printing parameter for printing the another layer of the plurality of layers according to the mapped adjustment behavior.

18. The 3D printing apparatus as claimed in claim 11, wherein a preset range of the printing temperature is default in the controller, and the controller confines the printing temperature within the preset range.

19. The 3D printing apparatus as claimed in claim 11, wherein the printing parameter comprises one or a combination of a moving speed of a print head, a location of the print head, a feeding amount of the print head, a printing height, and a printing temperature.

20. The 3D printing apparatus as claimed in claim 11, wherein each of the printing commands corresponds to a single row of G-code.
